(19) United States
(12) Patent Application Publication
(10) Pub. No.: US 2025/0270698 A1
(43) Pub. Date: Aug. 28, 2025

(54) BORON-CONTAINING PRECURSORS FOR THE ALD DEPOSITION OF BORON NITRIDE FILMS

(71) Applicant: Versum Materials US, LLC, Tempe, AZ (US)

(72) Inventors: Raymond N. Vrtis, Carlsbad, CA (US); Moo-Sung Kim, Sungnam-Si (KR); Haripin Chandra, San Marcos, CA (US); Xinjian Lei, Vista, CA (US)

(21) Appl. No.: 18/856,877

(22) PCT Filed: Apr. 12, 2023
(86) PCT No.: PCT/US2023/065686

§ 371 Date: Oct. 14, 2024

Related U.S. Application Data
(60) Provisional application No. 63/331,191, filed on Apr. 14, 2022.

(51) Int. Cl. C23C 16/455; C07F 5/02; C23C 16/30; C23C 16/44

(52) U.S. Cl. CPC C23C 16/45553; C07F 5/022; C23C 16/303; C23C 16/4408

(57) ABSTRACT

A boron-containing precursor having the structure of Formula I:

B(NR¹R²)ₙX₃₋ₙ (I),
wherein R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties. Deposition methods are also disclosed.

### CROSS-REFERENCE TO RELATED APPLICATIONS

This application is a National Stage filing under 35 U.S.C. 371 of International Patent Application No. PCT/US2023/065686, filed Apr. 12, 2023, which claims priority to Provisional Application No. 63/331,191, filed Apr. 14, 2022. Both applications are herein incorporated in their entirety.

### BACKGROUND OF THE INVENTION

Exemplary embodiments of the present invention relate to compositions and methods for forming a boron-containing film. More specifically, described herein are compounds, and composition and method comprising same, for the formation of a stoichiometric or a non-stoichiometric boron-containing film or material, or a boron-doped silicon containing film at one or more deposition temperatures.

Example technologies that can employ a high quality ALD boron nitride layer of the disclosure include insulating layers in a MISFET (metal-insulator-semiconductor field effect transistor), interconnect covering, such as copper, to help prevent power loss, lower resistivity, and prevent interconnect failure from power overloading. Other applications include finFETs, DRAM, flash memory, etc. Additional applications include as an interfacial layer of amorphous or crystalline BN that is deposited prior to dielectric deposition in MOSFET (metal-oxide-semiconductor FET) device architectures to prevent substrate diffusion into the high k material, thereby producing a device with a lower density of interfacial traps (Dit). Thus far, boron precursors such as haloboranes (e.g., BCl₃), trialkylborane, or boron alkoxide precursors have been used for boron doped films.

Haloborane compounds such as BCl₃ and BBr₃ are used to deposit boron nitride films by ALD, however, there is a concern with residual halides in the films which may negatively impact electrical performance. It is also known that aminoborane compounds such as (Me₂N)₃B can be used to deposit boron nitride films by ALD, however, while these films can be deposited using N₂ PEALD processes, the step coverage performance of N₂ based PEALD processes is poor. To date, it has not been possible to deposit boron nitride films from aminoborane precursors using NH₃ based PEALD processes at temperatures below 500° C.

Another problem with prior art boron nitrite precursors in ALD is the poor deposition at the bottom of features that typically leads to voids in a gapfill process. The gapfill process is a very important stage of semiconductor manufacturing as it is used to fill a high aspect ratio gap (or feature) with an insulating or conducting material. For example, shallow trench isolation, inter-metal dielectric layers, passivation layers, dummy gate, etc. As device geometries shrink (e.g., critical dimensions <20 nm) and thermal budgets are reduced, void-free filling of high aspect ratio spaces (e.g., AR>10:1) becomes increasingly difficult due to limitations of conventional deposition processes.

Most deposition methods—including boron nitrate depositions processes—deposit more material on the top region or on the walls of a trench than on the bottom region of a structure. The process often forms a mushroom shape film profile. As a result, the top part of a high aspect ratio structure sometimes pinches off prematurely leaving seams/voids within the structure's lower portions. This problem is more prevalent in small features.

Accordingly, there is a need in the art for a precursor that can deposit boron nitrite by ALD in a bottom-up process in very small aspect ratio features.

### BRIEF SUMMARY OF THE INVENTION

The present invention satisfies this need. Boron nitride films can be deposited from mixed haloaminoborane precursors such as, for example, B(NMe₂)₂Br, using both NH₃ and N₂ based PEALD processes. Unexpectedly, the inventors found that the films deposited using both NH₃ and N₂ PEALD with precursors such as, for example, B(NMe₂)₂Br, were thicker at the bottom compared to the top and sides of high aspect ratio patterned features, this “bottom-up” deposition is very unusual for any type of PEALD deposition.

In one aspect, the present invention provides a boron-containing precursor having the structure of Formula I:

B(NR¹R²)ₙX₃₋ₙ (I),
wherein R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties.

In another aspect, the present invention provides a composition comprising: (a) at least one compound having the structure of Formula I:

B(NR¹R²)ₙX₃₋ₙ (I),
wherein R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties; and (b) a solvent wherein the solvent has a boiling point and wherein the difference between the boiling point of the solvent and that of the at least one boron-containing precursor is 40° C. or less.

In yet another aspect, the present invention provides a method to deposit a boron-containing film onto at least a surface of a substrate which comprises the steps of: a. providing the substrate in a reactor; b. forming the boron-containing film on the surface in a deposition process selected from a chemical vapor deposition and atomic layer deposition process using a boron-containing precursor selected from a compound having the structure of Formula I:

B(NR¹R²)ₙX₃₋ₙ (I),
wherein R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties; c. purging the reactor with a purge gas; d. providing an nitrogen-containing source to deposit the film onto the at least one surface; e. purging the reactor with a purge gas; f. optionally introducing into the reactor at least one silicon-containing source; g. purging the reactor with a purge gas if needed following step f; h. providing a nitrogen-containing source to deposit the film onto the at least one surface; and i. purging the reactor with a purge gas, wherein steps b through i are repeated until a desired thickness of the film is obtained.

The embodiments of the invention can be used alone or in combinations with each other.

### BRIEF DESCRIPTION OF THE DRAWINGS

FIG. 1 is a plot showing film thickness achieved after 100 cycles of PEALD at 350° C. using various BDMABB exposure times;

FIG. 2 is a plot of BN film thickness versus number of PEALD cycles to determine the growth rate of boron nitride using BDMABB and N₂ plasma;

FIGS. 3A to 3D are TEM images of a 17:1 aspect ratio trench with BN deposited using 600 cycles of PEALD using BDMABB and N₂ plasma, which show film thicknesses at 4 locations along the trench (top, middle 1, middle 2 and bottom);

FIG. 4 is a plot of BN film thickness versus number of PEALD cycles to determine the growth rate of boron nitride using BDMABB and NH₃ plasma;

FIGS. 5A to 5D are TEM images of a 17:1 aspect ratio trench with BN deposited using 500 cycles of PEALD using BDMABB and NH₃ plasma, which show film thicknesses at 4 locations along the trench (top, middle 1, middle 2 and bottom);

FIG. 6 is a TEM image of BN films deposited onto patterned features (AR 5:1, 0.12 microns wide) using BDMABB and N₂ in a PEALD process;

FIG. 7 is a TEM image of BN films deposited onto patterned features (AR 5:1, 0.12 microns wide) using BDMABB and NH₃ in a PEALD process;

FIGS. 8A to 8E are TEM images following the deposition of BDMABB using an NH₃ PEALD process at a deposition temperature of 350° C., 200 W NH₃ plasma for 5 seconds, with a 3 second BDMABB pulse, with FIGS. 8B to 8E respectively being magnified images of features circled and noted as Top, MID1, MID2, and Bottom in FIG. 8A; and

FIGS. 9A to 9E are TEM images following the deposition of BDMABB using a N₂ PEALD process at a deposition temperature of 350° C., 200 W N₂ plasma for 5 seconds, with a 3 second BDMABB pulse, with FIGS. 9B to 9E respectively being magnified images of features circled and noted as Top, MID1, MID1, and Bottom in FIG. 9A.

### DETAILED DESCRIPTION OF THE INVENTION

All references, including publications, patent applications, and patents, cited herein are hereby incorporated by reference to the same extent as if each reference were individually and specifically indicated to be incorporated by reference and were set forth in its entirety herein.

The ensuing detailed description provides preferred exemplary embodiments only, and is not intended to limit the scope, applicability, or configuration of the invention. Rather, the ensuing detailed description of the preferred exemplary embodiments will provide those skilled in the art with an enabling description for implementing the preferred exemplary embodiments of the invention. Various changes may be made in the function and arrangement of elements without departing from the spirit and scope of the invention, as set forth in the appended claims.

The use of the terms “a” and “an” and “the” and similar referents in the context of describing the invention (especially in the context of the following claims) are to be construed to cover both the singular and the plural, unless otherwise indicated herein or clearly contradicted by context.

The use of recesses and features in the context of describing the invention (especially in the context of the following claims) is interchangeable, both are referring to vias, gaps, or areas between fins in semiconductor substrates.

As used herein and in the claims, the terms “comprising,” “comprises,” “including,” and “includes” are inclusive or open-ended and do not exclude additional unrecited elements, composition components, or method steps. Accordingly, these terms encompass the more restrictive terms “consisting essentially of” and “consisting of.” Unless specified otherwise, all values provided herein include up to and including the endpoints given, and the values of the constituents or components of the compositions are expressed in weight percent of each ingredient in the composition.

All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Variations of those preferred embodiments may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

For ease of reference, “microelectronic device” corresponds to semiconductor substrates, flat panel displays, phase change memory devices, solar panels and other products including solar cell devices, photovoltaics, and microelectromechanical systems (MEMS), manufactured for use in microelectronic, integrated circuit, energy collection, or computer chip applications. It is to be understood that the terms “microelectronic device,” “microelectronic substrate” and “microelectronic device structure” are not meant to be limiting in any way and include any substrate or structure that will eventually become a microelectronic device or microelectronic assembly. The microelectronic device can be patterned, blanketed, a control and/or a test device.

“Substantially free” is defined herein as less than 2 wt. %, preferably less than 1 wt. %, more preferably less than 0.5 wt. %, and most preferably less than 0.1 wt. %. “Substantially free” also includes 0.0 wt. %. The term “free of” means 0.0 wt. %.

As used herein, “about” is intended to correspond to ±5% of the stated value.

“Substantially free” is defined herein as less than 2 wt. %, preferably less than 1 wt. %, more preferably less than 0.5 wt. %, and even more preferably less than 0.1 wt. %. The term “free of” is defined herein as 0 wt. %.

As used herein, the term “halo” means halogen groups and includes, but is not limited to, fluoro, chloro, bromo, and iodo.

Compositions of the invention may be embodied in a wide variety of specific formulations, as hereinafter more fully described.

In all such compositions, wherein specific components of the composition are discussed in reference to weight percentage ranges including a zero lower limit, it will be understood that such components may be present or absent in various specific embodiments of the composition, and that in instances where such components are present, they may be present at concentrations as low as 0.001 weight percent, based on the total weight of the composition in which such components are employed.

Described herein are compositions and methods related to the formation of a stoichiometric or nonstoichiometric film or material comprising boron, such as without limitation a silicon oxide, a carbon-doped silicon oxide film, a silicon oxynitride, a carbon-doped silicon oxynitride films or combinations thereof with one or more temperatures, room temperature (e.g., about 25° C.) to about 1000° C., or from room temperature to about 400° C., or from room temperature to about 300° C., or from room temperature to about 200° C., or from room temperature to about 100° C. The films described herein are deposited in a deposition process such as, a chemical vapor deposition (CVD) process, an atomic layer deposition (ALD) or in an ALD-like process, such as without limitation, a plasma enhanced ALD or a plasma enhanced cyclic chemical vapor deposition process (CCVD).

In one aspect, the present invention provides a boron-containing precursor having the structure of Formula I:

B(NR¹R²)ₙX₃₋ₙ (I),
wherein R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties.

In certain embodiments of Formula I, R¹ and R² are linked together to form a ring. In one particular embodiment, R¹ and R² are selected from a linear or a branched C₃ to C₆ alkyl group and are linked to form a cyclic ring. As the skilled person will understand, where R¹ and R² are linked together to form a ring, R¹ would include a bond for linking to R² and vice versa. In these embodiments, the ring structure can be unsaturated such as, for example, a cyclic alkyl ring, or saturated, for example, an aryl ring. Further, in these embodiments, the ring structure can also be substituted or unsubstituted with one or more atoms or groups. Exemplary cyclic ring groups include, but not limited to, pyrrolidino, piperidino, and 2, 6-dimethylpiperidino groups.

In alternative embodiments of Formula I, R¹ and R² are not linked together to form a ring. In other embodiments, R¹ and R² are different; X is Cl, Br, I, or F, and n=1 or 2. In certain preferred embodiments of Formula I, R¹ and R² are bulky alkyls such as iso-propyl, tert-butyl, tert-pentyl.

In the formulas above and throughout the description, the term “alkyl” denotes a linear or branched functional group having from 1 to 10 or from 1 to 6 carbon atoms. Exemplary linear alkyl groups include, but are not limited to, methyl, ethyl, n-propyl, n-butyl, n-pentyl, and n-hexyl groups. Exemplary branched alkyl groups include, but are not limited to, iso-propyl, iso-butyl, sec-butyl, tert-butyl, iso-pentyl, tert-pentyl, iso-hexyl, and neo-hexyl. In certain embodiments, the alkyl group may have one or more functional groups attached thereto such as, but not limited to, an alkoxy group, a dialkylamino group or combinations thereof, attached thereto. In other embodiments, the alkyl group does not have one or more functional groups attached thereto. The alkyl group may be saturated or, alternatively, unsaturated. The alkyl group may also be substituted or having one or more heteroatoms such as a halide or O or unsubstituted.

In the formulas above and throughout the description, the term “cyclic alkyl” denotes a cyclic functional group having from 4 to 10 carbon atoms. Exemplary cyclic alkyl groups include, but are not limited to, cyclobutyl, cyclopentyl, cyclohexyl, and cyclooctyl groups.

In the formulas above and throughout the description, the term “alkenyl group” denotes a group which has one or more carbon-carbon double bonds and has from 2 to 10 or from 2 to 10 or from 2 to 6 carbon atoms.

In the formulas above and throughout the description, the term “alkynyl group” denotes a group which has one or more carbon-carbon triple bonds and has from 3 to 10 or from 2 to 10 or from 2 to 6 carbon atoms.

In the formulas above and throughout the description, the term “aryl” denotes an aromatic cyclic functional group having from 4 to 10 carbon atoms, from 5 to 10 carbon atoms, or from 6 to 10 carbon atoms. Exemplary aryl groups include, but are not limited to, phenyl, benzyl, chlorobenzyl, tolyl, o-xylyl, 1,2,3-triazolyl, pyrrrolyl, and furanyl, pyridazinyl, pyrimidinyl, pyrazinyl, and imidazolyl.

In the formulas above and throughout the description, the term “amino” denotes an organoamino group having from 1 to 10 carbon atoms derived from an organoamines with formula of HNR²R³. Exemplary amino groups include, but are not limited to, secondary amino groups derived from secondary amines such as dimethylamino(Me₂N—), diethyamino(Et₂N—), ethylmethylamino (EtMeN—), di-isopropylamino (ⁱPr₂N—); primary amino groups derived from primary amines such as methylamino (MeNH—), ethylamine (EtNH—), iso-propylamino (ⁱPrNH—), sec-butylamino (^{s}BuNH—), tert-butylamino (^{t}BuNH—).

Examples of boron-containing precursors having a chemical structure represented by Formula I include bis(dimethylamino)chloroborane, bis(dimethylamino)bromoborane, bis(dimethylamino)iodoborane, bis(diethylamino)chloroborane, bis(diethylamino)bromoborane, bis(diethylamino)iodoborane, bis(ethylmethylamino)chloroborane, bis(ethylmethylamino)bromoborane, bis(ethylmethylamino)iodoborane, (di-iso-propylamino)dichloroborane, (di-iso-propylamino)dibromoborane, (di-iso-propylamino)diiodoborane (pyrrolidino)chloroborane, (pyrrolidino)bromoborane, (pyrrolidino)iodoborane, (2-methyl-pyrrolidino)chloroborane, (2-methyl-pyrrolidino)bromoborane, (2-methyl-pyrrolidino)iodoborane, (2,5-dimethyl-pyrrolidino)chloroborane, (2,5-dimethyl-pyrrolidino)bromoborane, (2,5dimethyl-pyrrolidino)iodoborane (piperidino)chloroborane, (piperidino)bromoborane, (piperidino)iodoborane, (2,6-dimethyl-piperidino)dichloroborane, (2,6-dimethyl-piperidino)dibromoborane, and (2,6-dimethyl-piperidino)diiodoborane. A preferred boron-containing precursor is bis(dimethylamino)bromoborane or bis(ethylmethylamino)bromoborane.

In some embodiments, the boron-containing precursor represented by Formula I is at least one selected from the group consisting of In some embodiments, bis(ethylmethylamino)chloroborane, bis(ethylmethylamino)bromoborane, bis(ethylmethylamino)iodoborane; (2-methyl-pyrrolidino)chloroborane, (2-methyl-pyrrolidino)bromoborane, (2-methyl-pyrrolidino)iodoborane, (2,5-di-methyl-pyrrolidino)chloroborane, (2,5-dimethyl-pyrrolidino)bromoborane, and (2,5-dimethyl-pyrrolidino)iodoborane.

In other embodiments, the boron-containing precursor represented by Formula I is at least one selected from the group consisting of

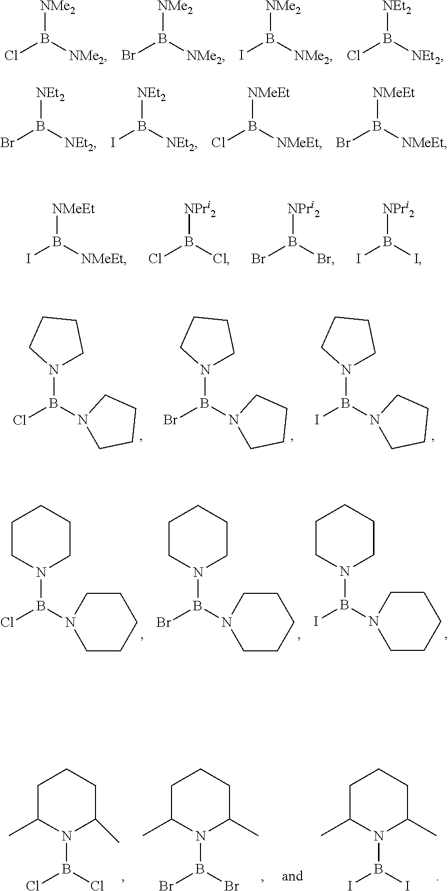

During manufacturing of electronic devices such as an integrated circuit, features or recesses such as gaps, trenches, or areas between fins can be created on a substrate surface. Filling the features or recesses can take a variety of forms, depending on the specific application. A typical recess filling process may be subjected to drawbacks including void formation in the recesses. Voids and seams may be formed when the filling material forms a constriction near a top of the recess before the recess is completely filled. Such voids and seams may compromise isolation of the devices on the integrated circuit as well as its overall structural integrity. Unexpectedly, the inventors found that the films deposited according to the methods described below using both NH₃ and N₂ PEALD with the above-identified boron-containing precursors represented by Formula I such as, for example, bis(dimethylamino)bromoborane (BDMABB), are thicker at the bottom compared to the top and sides of high aspect ratio patterned features, this “bottom-up” deposition is very unusual for any type of PEALD deposition and can be potentially employed for gap fill application in fabrication of semi-conductor devices. Not bound by theory, it is believed that that the by-product during the PEALD deposition is HX such as HBr or HCl which can potentially etch as-deposited silicon nitride on the side wall of the features such as vias or trenches, as a result, the silicon nitride growth rate is higher on the bottom surface than on the side walls, thus unexpectedly making the bottom-up fill possible. Bottom-up depositions were observed for high aspect ratio features where the aspect ratio is defined as the depth of the feature divided by the width of the feature such as, for example, 5:1 or higher, 8:1 or higher, 10:1 of higher, 20:1 higher, 30:1 or higher, 40:1 of higher, 40:1 higher, 50:1 or higher, 60:1 of higher, 80:1 higher, and 100:1 or higher. Alternatively, bottom up depositions were observed for high aspect ratio features where the aspect ratio is defined as the depth of the feature divided by the width of the feature such as, for example, from 5:1 to 100:1, from 8:1 to 100:1, from 10:1 to 100:1, from 20:1 to 100:1, from 30:1 to 100:1, from 40:1 to 100:1, from 40:1 to 100:1, from 50:1 to 100:1, from 60:1 to 100:1, and from 80:1 to 100:1.

Thus, in one aspect, provided herewith is a method for depositing a boron-containing film such as, for example, a boron nitrite film, in a high aspect ratio feature from the bottom up such that the film has a growth rate that is higher on the bottom surface than on side wall surfaces of the high aspect ratio feature. The method comprises the steps of:
a. providing a substrate in a reactor;
b. introducing into the reactor at least one boron-containing precursor represented by Formula I:

B(NR¹R²)ₙX₃₋ₙ (I),
wherein R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties;
c. purging the reactor with a purge gas;
d. providing a nitrogen-containing plasma source to deposit the film onto the at least one surface; and
e. purging the reactor with a purge gas,
wherein steps b through e are repeated until a desired thickness of the film is obtained. In one particular embodiment, the depositing step is conducted at one or more temperatures ranging from about room temperature to about 1000° C., or from room temperature to about 400° C., or from room temperature to about 300° C., or from room temperature to about 200° C., or from room temperature to about 100° C. The preferred nitrogen-containing source can be selected from the group consisting of N₂ plasma, ammonia plasma, and N₂ plasma/ammonia plasma.

In another aspect, disclosed is a composition comprising: (a) at least one compound having the structure of Formula I:

B(NR¹R²)ₙX₃₋ₙ (I),
wherein R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties; and (b) a solvent wherein the solvent has a boiling point and wherein the difference between the boiling point of the solvent and that of the at least one boron-containing precursor is 40° C. or less.

In certain embodiments of the composition described herein, exemplary solvents can include, without limitation, ether, tertiary amine, alkyl hydrocarbon, aromatic hydrocarbon, tertiary aminoether, and combinations thereof. In certain embodiments, the difference between the boiling point of the organoaminodisilane and the boiling point of the solvent is 40° C. or less. It is believed that some solvent may help stabilize the organoaminoborane in either liquid phase or even gas phase during storage or delivery.

In another aspect, there is provided a method for forming a boron-containing film on at least one surface of a substrate comprising: providing the at least one surface of the substrate in a reaction chamber; and forming the boron-containing film on the at least one surface by a deposition process chosen from a chemical vapor deposition process and an atomic layer deposition process using a boron-containing precursor represented by Formula I:

B(NR¹R²)ₙX₃₋ₙ (I),
wherein R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties.

In another aspect, there is provided a method of forming a boron oxide or boron carboxide film via an atomic layer deposition process or ALD-like process, the method comprising the steps of:
a. providing a substrate in a reactor;
b. introducing into the reactor at least one boron-containing precursor represented by Formula I:

B(NR¹R²)ₙX₃₋ₙ (I),
wherein R¹ is selected from a linear C₁ to C₆ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties;
c. purging the reactor with a purge gas;
d. providing a nitrogen-containing source to deposit the film onto the at least one surface; and
e. purging the reactor with a purge gas,
wherein steps b through e are repeated until a desired thickness of the film is obtained. In one particular embodiment, the depositing step is conducted at one or more temperatures ranging from about room temperature to about 1000° C., or from room temperature to about 400° C., or from room temperature to about 300° C., or from room temperature to about 200° C., or from room temperature to about 100° C.

In another aspect, there is provided a method of forming a boron doped silicon oxide, boron doped silicon carboxide film via an atomic layer deposition process or ALD-like process, the method comprising the steps of:
a. providing a substrate in a reactor;
b. introducing into the reactor at least one boron-containing precursor represented by the Formula I:

B(NR¹R²)ₙX₃₋ₙ (I),
wherein R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties;
c. purging the reactor with a purge gas;
d. providing a nitrogen-containing source to deposit the film onto the at least one surface;
e. purging the reactor with a purge gas;
f. introducing into the reactor at least one silicon-containing source;
g. purging the reactor with a purge gas;
h. providing an oxygen-containing source to deposit the film onto the at least one surface; and
i. purging the reactor with a purge gas,
wherein steps b through i are repeated until a desired thickness of the film is obtained. In some embodiments, steps b to e are repeated and then step f to i are repeated to deposit a nanolaminate layer consisting of boron oxide and silicon oxide. In other embodiments, step f to i can be performed and repeated, followed by repeating steps b to e. For the nanolaminate, the thickness of silicon oxide can range from 1 Å to 5000 Å, 10 Å to 2000 Å, 50 Å to 1500 Å, 50 Å to 1000 Å, 50 Å to 500 Å whereas the thickness of boron oxide ranges from 1 Å to 5000 Å, 10 Å to 2000 Å, 50 Å to 1500 Å, 50 Å to 1000 Å, 50 Å to 500 Å. In one particular embodiment, the depositing step is conducted at one or more temperatures ranging from about room temperature to about 1000° C., or from room temperature to about 400° C., or from room temperature to about 300° C., or from room temperature to about 200° C., or from room temperature to about 100° C. In another particular embodiment, the deposition step is conducted at temperature less than 400° C. when a silicon-containing source has at least one SiH₃ group such as di-iso-propylaminosilane, di-sec-butylaminosilane, di-iso-propylaminodisilane, di-sec-butylaminodisilane is being employed.

In yet another aspect, there is provided a method of forming a boron nitride, boron carbonitride, or boron carboxynitride film via an atomic layer deposition process or ALD-like process, the method comprising the steps of:
a. providing a substrate in a reactor;
b. introducing into the reactor at least one boron-containing precursor represented by Formula I:

B(NR¹R²)ₙX₃₋ₙ (I),
wherein R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₆ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties;
c. purging the reactor with a purge gas;
d. providing a nitrogen-containing source to deposit the film onto the at least one surface; and
e. purging the reactor with a purge gas,
wherein steps b through e are repeated until a desired thickness of the film is obtained. In one particular embodiment, the depositing step is conducted at one or more temperatures ranging from about room temperature to about 1000° C., or from room temperature to about 400° C., or from room temperature to about 300° C., or from room temperature to about 200° C., or from room temperature to about 100° C.

In another aspect, there is provided a method of forming a boron doped silicon nitride, boron doped silicon carbonitride, boron doped silicon carboxynitride film via an atomic layer deposition process or ALD-like process, the method comprising the steps of:
a. providing a substrate in a reactor;
b. introducing into the reactor at least one boron-containing precursor represented by Formula I:

B(NR¹R²)ₙX₃₋ₙ (I),
wherein R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group; R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group; X is Cl, Br, I, or F; and n=1 or 2, wherein R¹ and R² are optionally linked together to form a ring selected from a substituted or unsubstituted aromatic ring or a substituted or unsubstituted aliphatic ring, and wherein R¹ and R² may be the same moiety or different moieties;
c. purging the reactor with a purge gas;
d. providing an nitrogen-containing source to deposit the film onto the at least one surface;
e. purging the reactor with a purge gas;
f. introducing into the reactor at least one silicon-containing source;
g. purging the reactor with a purge gas;
h. providing a nitrogen-containing source to deposit the film onto the at least one surface; and
i. purging the reactor with a purge gas,
wherein steps b through g are repeated until a desired thickness of the film is obtained. In some embodiments, steps b to e are repeated and then step f to i are repeated to deposit a nanolaminate layer consisting of boron nitride and silicon nitride. In other embodiments, step f to i can be performed and repeated first, followed by repeating steps b to e. For the nanolaminate, the thickness of silicon nitride can range from 1 Å to 5000 Å, 10 Å to 2000 Å, 50 Å to 1500 Å, 50 Å to 1000 Å, 50 Å to 500 Å whereas the thickness of boron nitride ranges from 1 Å to 5000 Å, 10 Å to 2000 Å, 50 Å to 1500 Å, 50 Å to 1000 Å, 50 Å to 500 Å. In one particular embodiment, the depositing step is conducted at one or more temperatures ranging from about room temperature to about 1000° C., or from room temperature to about 400° C., or from room temperature to about 300° C., or from room temperature to about 200° C., or from room temperature to about 100° C. In another particular embodiment, the deposition step is conducted at temperature less than 400° C. when a silicon-containing source has at least one SiH₃ group such as di-iso-propylaminosilane, di-sec-butylaminosilane, di-iso-propylaminodisilane, di-sec-butylaminodisilane is being employed.

In embodiments of the method wherein a silicon-containing source is used, the silicon-containing source includes, but not limited to, trisilylamine (TSA), bis(disiylamino)silane, bis(tert-butylamino)silane (BTBAS), bis(dimethylamino)silane, bis(diethylamino)silane, bis(ethylmethylamino)silane, tris(dimethylamino)silane, tris(ethylmethylamino)silane, tetrakis)dimethylamino)silane, di-iso-propylaminosilane, di-sec-butylaminosilane, di-tert-butylaminosilane, 2,6-dimethylpiperidinosilane, 2,2,6,6-tetramethylpiperidinosilane, cyclohexyl-iso-propylaminosilane, phenylmethylaminosilane, phenylethylaminodisilane, di-cyclohexylaminosilane, di-iso-propylaminodisilane, di-sec-butylaminodisilane, di-tert-butylaminodisilane, 2,6-dimethylpiperidinodisilane, 2,2,6,6-tetramethylpiperidinodisilane, cyclohexyl-iso-propylaminodisilane, phenylmethylaminodisilane, phenylethylaminodisilane, di-cyclohexylaminodisilane, dimethylaminotrimethylsilane, dimethylaminotrimethylsilane, di-iso-propylaminotrimethylsilane, piperidinotrimethylsilane, 2,6-dimethylpiperidinotrimethylsilane, di-sec-butylaminotrimethylsilane, iso-propyl-sec-butylaminotrimethylsilane, tert-butylaminotrimethylsilane, iso-propylaminotrimethylsilane, diethylaminodimethylsilane, dimethylaminodimethylsilane, di-iso-propylaminodimethylsilane, piperidinodimethylsilane, 2,6-dimethylpiperidinodimethylsilane, di-sec-butylaminodimethylsilane, iso-propyl-sec-butylaminodimethylsilane, tert-butylaminodimethylsilane, iso-propylaminodimethylsilane, tert-pentylaminodimethylaminosilane, bis(dimethylamino)methylsilane, bis(diethylamino)methylsilane, bis(di-iso-propylamino)methylsilane, bis(iso-propyl-sec-butylamino)methylsilane, bis(2,6-dimethylpiperidino)methylsilane, bis(iso-propylamino)methylsilane, bis(tert-butylamino)methylsilane, bis(sec-butylamino)methylsilane, bis(tert-pentylamino)methylsilane, di-iso-propylaminodisilane, and di-sec-butylaminodisilane, di-iso-propylaminotrisilylamine, diethylaminotrisilylamine, iso-propylaminotrisilylamine, and cyclohexylmethylaminotrisilylamine, 2-dimethylamino-2,4,4,6,6-pentamethylcyclotrisiloxane, 2-diethylamino-2,4,4,6,6-pentamethylcyclotrisiloxane, 2-ethylmethylamino-2,4,4,6,6-pentamethylcyclotrisiloxane, 2-iso-propylamino-2,4,4,6,6-pentamethylcyclotrisiloxane, 2-dimethylamino-2,4,4,6,6,8,8-heptamethylcyclotetrasiloxane, 2-diethylamino-2,4,4,6,6,8,8-heptamethylcyclotetrasiloxane, 2-ethylmethylamino-2,4,4,6,6,8,8-heptamethylcyclotetrasiloxane, 2-iso-propylamino-2,4,4,6,6,8,8-heptamethylcyclotetrasiloxane, 2-dimethylamino-2,4,6-trimethylcyclotrisiloxane, 2-diethylamino-2,4,6-trimethylcyclotrisiloxane, 2-ethylmethylamino-2,4,6-trimethylcyclotrisiloxane, 2-iso-propylamino-2,4,6-trimethylcyclotrisiloxane, 2-dimethylamino-2,4,6,8-tetramethylcyclotetrasiloxane, 2-diethylamino-2,4,6,8-tetramethylcyclotetrasiloxane, 2-ethylmethylamino-2,4,6,8-tetramethylcyclotetrasiloxane, and 2-iso-propylamino-2,4,6,8-tetramethylcyclotetrasiloxane, 2-pyrrolidino-2,4,6,8-tetramethylcyclotetrasiloxane, and 2-cyclohexylmethylamino-2,4,6,8-tetramethylcyclotetrasiloxane.

The deposition methods disclosed herein may involve one or more purge gases. The purge gas, which is used to purge away unconsumed reactants and/or reaction byproducts, is an inert gas that does not react with the precursors. Exemplary purge gases include, but are not limited to, argon (Ar), nitrogen (N₂), helium (He), neon, hydrogen (H₂), and mixtures thereof. In certain embodiments, a purge gas such as Ar is supplied into the reactor at a flow rate ranging from about 10 to about 2000 sccm for about 0.1 to 1000 seconds, thereby purging the unreacted material and any byproduct that may remain in the reactor.

In certain embodiments, the boron oxide, boron silicon oxide or boron doped silicon carboxide films deposited using the methods described herein are formed in the presence of oxygen-containing source such as ozone, water (H₂O) (e.g., deionized water, purifier water, and/or distilled water), oxygen (O₂), ozone plasma, oxygen plasma, NO, N₂O, NO₂, carbon monoxide (CO), carbon dioxide (CO₂) and combinations thereof. The oxygen-containing source gas can be passed through a plasma generator in situ or remote to provide oxygen-containing plasma source comprising oxygen such as an oxygen plasma, an oxygen/argon plasma, an oxygen/helium plasma, an ozone plasma, a water plasma, a nitrous oxide plasma, or a carbon dioxide plasma.

In certain embodiments, the boron-containing films comprise boron, silicon and nitrogen to provide a boron nitride, boron doped silicon nitride or boron doped silicon carbonitride film. In these embodiments, the boron-containing films deposited using the methods described herein are formed in the presence of nitrogen-containing source. A nitrogen-containing source may be introduced into the reactor in the form of at least one nitrogen source and/or may be present incidentally in the other precursors used in the deposition process. Suitable nitrogen-containing source gases may include, for example, ammonia, hydrazine, monoalkylhydrazine (e.g., methylhydrazine, tert-butylhydrazine), dialkylhydrazine (e.g., 1,1-dimethylhydrazine, 1,2-dimethylhydrazine), organoamine (e.g., methylamine, dimethylamine, ethylamine, diethylamine, tert-butylamine), organoamine plasma, nitrogen, nitrogen plasma, nitrogen/hydrogen, nitrogen/helium, nitrogen/argon plasma, ammonia plasma, ammonia/helium plasma, ammonia/argon plasma, ammonia/nitrogen plasma, NF₃, NF₃ plasma, and mixtures thereof.

In certain embodiments, the boron-containing films comprise boron content ranging from 0.5 to 50% measured by XPS, preferably 1 to 20% and can be selected form the group consisting of boron oxide, boron nitride, boron carbonitride, boron doped silicon oxide, boron doped silicon carboxide, a boron doped silicon oxynitride, boron doped silicon nitride, boron doped silicon carbonitride which can be employed in the fabrication of semi-conductor processes such as solid state diffusion layer for production of FinFET.

The respective step of supplying the boron-containing precursors, oxygen source, and/or other precursors, source gases, and/or reagents may be performed by changing the time for supplying them to change the stoichiometric composition of the resulting film.

Energy is applied to the at least one of the precursors, oxygen containing source, or combination thereof to induce reaction and to form the film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively, a remote plasma-generated process in which plasma is generated outside of the reactor and supplied into the reactor.

The at least one precursors may be delivered to the reaction chamber such as a plasma enhanced cyclic CVD or PEALD reactor or a batch furnace type reactor in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

For those embodiments wherein the precursor described herein is used in a composition comprising a solvent and an at least one boron-containing precursor and optionally silicon-containing precursor described herein, the solvent or mixture thereof selected does not react with the boron-containing precursor. The amount of solvent by weight percentage in the composition ranges from 0.5% by weight to 99.5% or from 10% by weight to 75%. In this or other embodiments, the solvent has a boiling point (b.p.) similar to the b.p. of the precursor or the difference between the b.p. of the solvent and the b.p. of the precursor is 40° C. or less, 30° C. or less, or 20° C. or less, or 10° C. or less. Alternatively, the difference between the boiling points ranges from any one or more of the following end-points: 0, 10, 20, 30, or 40° C. Examples of suitable ranges of b.p. difference include without limitation, 0 to 40° C., 20° C. to 30° C., or 10° C. to 30° C. Examples of suitable solvents in the compositions include, but are not limited to, an ether (such as 1,4-dioxane, dibutyl ether), a tertiary amine (such as pyridine, 1-methylpiperidine, 1-ethylpiperidine, N,N′-Dimethylpiperazine, N,N,N′,N′-Tetramethylethylenediamine), a nitrile (such as benzonitrile), an alkane (such as octane, nonane, dodecane, ethylcyclohexane), an aromatic hydrocarbon (such as toluene, mesitylene), a tertiary aminoether (such as bis(2-dimethylaminoethyl) ether), or mixtures thereof.

As previously mentioned, the purity level of the boron-containing precursor is sufficiently high enough to be acceptable for reliable semiconductor manufacturing. In certain embodiments, the precursor described herein comprise less than 2% by weight, or less than 1% by weight, or less than 0.5% by weight of one or more of the following impurities: free amines, free halides or halogen ions, and higher molecular weight species. Higher purity levels of the precursor described herein can be obtained through one or more of the following processes: purification, adsorption, and/or distillation.

In one embodiment of the method described herein, a plasma enhanced cyclic deposition process such as PEALD-like or PEALD may be used wherein the deposition is conducted using the precursor(s) and an oxygen-containing or nitrogen-containing source. The PEALD-like process is defined as a plasma enhanced cyclic CVD process but still provides high conformal boron-containing films.

In certain embodiments, the gas lines connecting from the precursor canisters to the reaction chamber are heated to one or more temperatures depending upon the process requirements and the container of the precursor is kept at one or more temperatures for bubbling. In other embodiments, a solution comprising the precursor is injected into a vaporizer kept at one or more temperatures for direct liquid injection.

A flow of argon and/or other gas may be employed as a carrier gas to help deliver the vapor of the at least one silicon precursor to the reaction chamber during the precursor pulsing. In certain embodiments, the reaction chamber process pressure is about 50 m Torr to 10 Torr. In other embodiments, the reaction chamber process pressure can be up to 760 Torr

In a typical PEALD or a PEALD-like process such as a PECCVD process, the substrate such as a silicon oxide substrate is heated on a heater stage in a reaction chamber that is exposed to the precursor initially to allow the complex to chemically adsorb onto the surface of the substrate.

As previously mentioned, a purge gas such as argon purges away unabsorbed excess complex from the process chamber. After sufficient purging, an oxygen source may be introduced into reaction chamber to react with the absorbed surface followed by another gas purge to remove reaction by-products from the chamber. The process cycle can be repeated to achieve the desired film thickness. In some cases, pumping can replace a purge with inert gas or both can be employed to remove unreacted precursors.

In this or other embodiments, it is understood that the steps of the methods described herein may be performed in a variety of orders, may be performed sequentially, may be performed concurrently (e.g., during at least a portion of another step), and any combination thereof. The respective step of supplying the precursors and the oxygen-containing or nitrogen-containing source gases may be performed by varying the duration of the time for supplying them to change the stoichiometric composition of the resulting dielectric film. Also, purge times after precursor or oxygen-containing or nitrogen-containing steps can be minimized to <0.1 s so that throughput can be improved.

Various commercial ALD reactors such as single wafer, semi-batch, batch furnace or roll to roll reactor can be employed for depositing the boron-containing film or materials described herein.

Process temperature for the method described herein use one or more of the following temperatures as endpoints: 0, 25, 50, 75, 100, 125, 150, 175, 200, 225, 250, 275, 300, 325, 350, 375, 400, 425, 450, 500, 525, 550, 575, 600. Exemplary temperature ranges include, but are not limited to the following: from about 0° C. to about 600° C.; or from about 25° C. to about 500° C.; or from about 150° C. to about 400° C.; or from about 25° C. to about 300° C., or from about 25° C. to about 200° C.

As mentioned previously, the method described herein may be used to deposit a boron-containing film on at least a portion of a substrate. Examples of suitable substrates include but are not limited to, silicon, SiO₂, Si₃N₄, OSG, FSG, silicon carbide, hydrogenated silicon carbide, silicon nitride, hydrogenated silicon nitride, silicon carbonitride, hydrogenated silicon carbonitride, boronitride, antireflective coatings, photoresists, germanium, germanium-containing, boron-containing, Ga/As, a flexible substrate, organic polymers, porous organic and inorganic materials, metals such as copper and aluminum, and diffusion barrier layers such as but not limited to TiN, Ti(C)N, TaN, Ta(C)N, Ta, W, or WN. The films are compatible with a variety of subsequent processing steps such as, for example, chemical mechanical planarization (CMP) and anisotropic etching processes.

The features and advantages are more fully shown by the illustrative examples discussed below.

### EXAMPLES

In the following examples, unless stated otherwise, properties were obtained from sample films that were deposited onto medium resistivity (14-17 S2-cm) single crystal silicon wafer substrates. All film depositions were performed using an ALD tool manufactured by CN-1 which has a showerhead design and uses 13.56 MHz, direct plasma in typical process conditions, unless stated otherwise, the chamber pressure was fixed at a pressure ranging from about 1 to about 5 torr. Additional inert gas such as argon or nitrogen was used to maintain chamber pressure. The organoborane precursor was delivered by bubbling 50 sccm Argon through the vessel while the vessel is held at 50° C. Typical RF power used was 200 W over electrode area of 200 mm wafer to provide a power density of 0.64 W/cm².

The refractive index (RI) and thickness for the deposited films were measured either using an ellipsometer (e.g., Ellipso Technology's model Elli-SE-UaM12 at room temperature) or transmission electron microscopy (JEOL's HRTEM, model JEM-3010). Film composition was analyzed using x-ray photoectron spectroscopy (XPS), (Thermo Fisher Scientific K-Alpha+XPS). Film crystallinity was measured by XRD using (Rigaku Corp, model SmartLab). Film surface roughness was measured by atomic force microscopy (AFM using (XE-150, Park systems). All measurements were conducted in accordance with conventional methods.

### Example 1: PEALD Boron Nitride Film Using Bis(dimethylamino)bromoborane (BDMABB) and Nitrogen Plasma

The silicon wafer was loaded into the CN-1 reactor equipped with showerhead design with 13.56 MHZ direct plasma and heated to 350° C. with chamber pressure of 2 torr. Bis(dimethylamino)bromoborane (BDMABB) was used as boron nitride precursor and delivered to the reaction chamber by bubbling 50 sccm argon through the liquid held at 50° C. The ALD cycle was comprised of the following process steps:
a. Prepare the reactor and load wafer
   Chamber pressure: 2 torr
b. Introduce the BDMABB precursor to the reactor
   Bubbling: BDMABB precursor 50 sccm Ar flow
   N₂ flow: 1000 sccm
   BDMABB pulse: from 1 to 5 seconds
c. Purge excess precursor
   N₂ Flow: 1000 sccm
   Purge time: 20 seconds
d. Introduce plasma
   N₂ flow: 1000 sccm
   Plasma power: 200 W
   Plasma pulse: 5 second
e. Purge
   N₂ Flow: 1000 sccm
   Purge time: 20 seconds

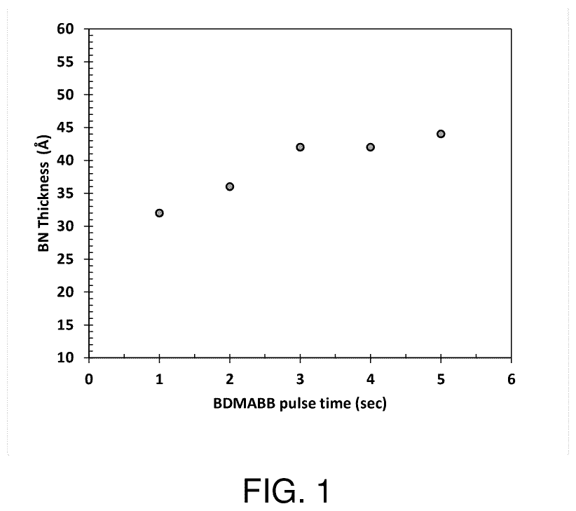

Steps b to e were repeated for 100 cycles with BDMABB pulses at 1, 2, 3, 4, and 5 seconds respectively for boron precursor saturation tests as shown in FIG. 1 which demonstrates BDMABB reaches ALD self-limiting at about 3 seconds. Table 1 shows the films thickness and refractive indices for the films deposited where steps b to e were repeated for 100, 250, 500 and 600 cycles respectively.

TABLE 1
Boron nitride thickness and refractive index for films deposited
at varying number of PEALD cycles using BDMABB and N₂ plasma.

| # of cycles | Film Thickness (Å) | Refractive Index |
|---|---|---|
| 100 | 42 | 1.98 |
| 250 | 110 | 1.88 |
| 500 | 227 | 1.76 |
| 600 | 271 | 1.74 |

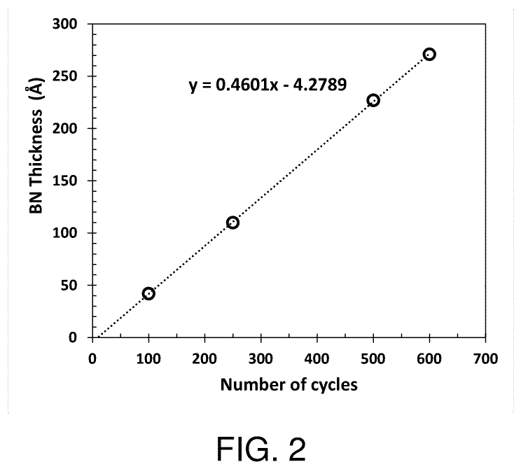

The growth rate for born nitride was calculated from graph of thickness v. number of cycles as 0.46 Å/cycle as shown in FIG. 2.

Films were deposited using 600 cycles for analysis. The XPS analysis shows the films contain 53.4 atomic % boron, 36.4 atomic % Nitrogen, 7.0 atomic % carbon, and 3.2 atomic % oxygen (from air). The XRD diffraction pattern showed no features, indicating that the films were amorphous. The AFM analysis indicated that the films were had an average roughness of 2.05 nm.

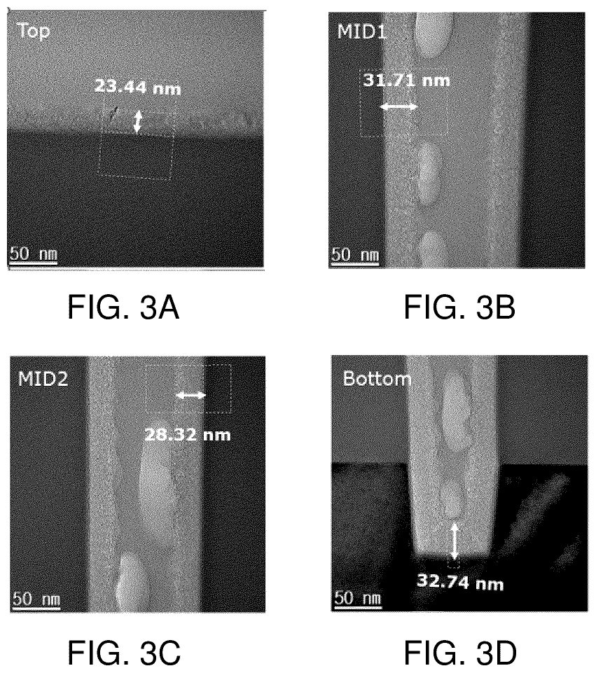

Boron nitride films were deposited from BDMABB onto wafers with trenches etched into silicon oxide followed by a thin layer of silicon nitride deposited by thermal CVD in order to increase the aspect ratio's. TEM images were taken of trenches which were 0.14 microns wide by 2.38 microns deep for an aspect ratio (AR) of 17. Boron Nitride films were deposited using 600 cycles of PEALD with BDMABB and N₂ plasma. Film thickness measurements were made at the top of the features (23.44 nm), middle 1 along the sidewall (31.71 nm), middle 2 further down along the sidewall (28.32 nm) and at the bottom of the feature (32.74 nm) as shown in FIG. 3 which shows that the step coverage for the BN films were all above 100% showing that there is bottom-up filling of the features.

### Example 2: PEALD Boron Nitride Film Using BDMABB, and Ammonia Plasma

The silicon wafer was loaded into the CN-1 reactor equipped with showerhead design with 13.56 MHZ direct plasma and heated to 350° C. with chamber pressure of 2 torr. BDMABB was used as boron precursor and delivered to the reaction chamber by bubbling 50 sccm argon through the liquid held at 50° C. The ALD cycle was comprised of the following process steps:
a. Prepare the reactor and load wafer
   Chamber pressure: 2 torr
b. Introduce the BDMABB precursor to the reactor
   Bubbling: BDMABB precursor 50 sccm Ar flow
   Argon flow: 1000 sccm
   BDMABB pulse: 3 seconds
c. Purge excess precursor
   Argon flow: 1000 sccm
   Purge time: 20 seconds
d. Introduce plasma
   Argon flow: 1000 sccm
   NH₃ Flow: 100 sccm
   Plasma power: 200 W
   Plasma pulse: 5 second
e. Purge
   Argon flow: 1000 sccm
   Purge time: 20 seconds

Table 2 shows the films thickness and refractive indices for the films deposited where steps b to e were repeated for 100, 250, and 500 cycles respectively.

TABLE 2
Boron nitride thickness and refractive index for films deposited
at varying number of PEALD cycles using BDMABB and NH₃ plasma.

| # of cycles | Film Thickness (Å) | Refractive Index |
|---|---|---|
| 100 | 43 | 1.88 |
| 250 | 118 | 1.85 |
| 500 | 203 | 1.74 |

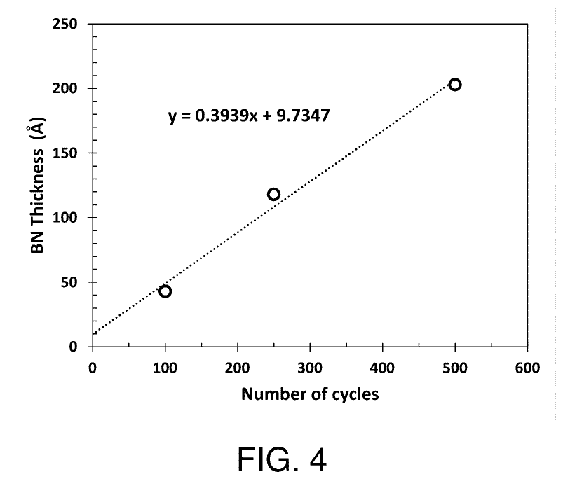

The growth rate for born nitride was calculated from graph of thickness v. number of cycles as 0.39 Å/cycle as shown in FIG. 4.

Films were deposited using 500 cycles for analysis. The XPS analysis shows the films contain 56.2 atomic % boron, 38.7 atomic % Nitrogen, 2.6 atomic % carbon, and 2.5 atomic % oxygen (from air). The XRD diffraction pattern showed no features, indicating that the films were amorphous. The AFM analysis indicated that the films were had an average roughness of 0.44 nm.

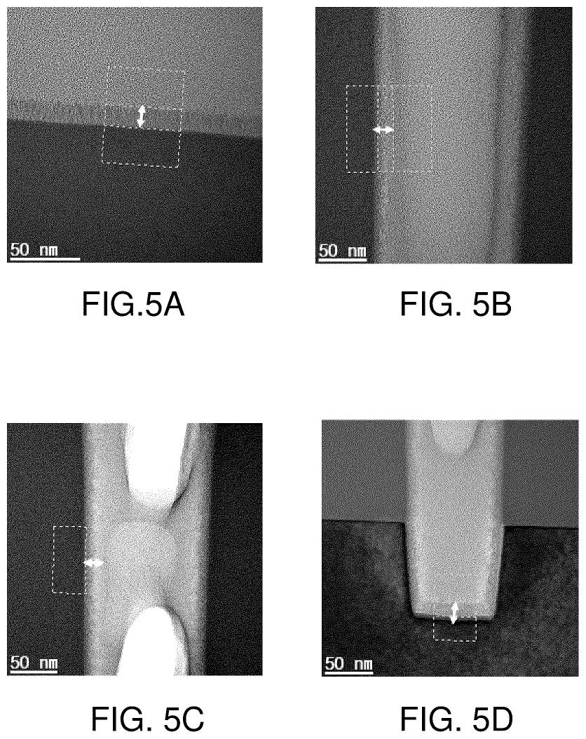

Boron nitride films were deposited from BDMABB onto wafers with trenches etched into silicon oxide followed by a thin layer of silicon nitride deposited by thermal CVD in order to increase the aspect ratios. TEM images were taken of trenches which were 0.14 microns wide by 2.38 microns deep for an aspect ratio (AR) of 17. Film thickness measurements were made at the top of the features (15.15 nm) as shown in FIG. 5A, middle 1 along the sidewall (16.11 nm) as shown in FIG. 5B, middle 2 further down along the sidewall (15.07 nm) as shown in FIG. 5C, and at the bottom of the feature (14.56 nm) as shown in FIG. 5D, revealing that the step coverage for the BN films were between 106% and 93%.

### Example 3: Analytical Data for the Films of Example 1 and Example 2

In Examples 1 and 2, BN films were deposited via PEALD using BDMABB with N₂ (Example 1) and NH₃ (Example 2) based plasmas as follows. The wafer temperature was 350° C., the chamber pressure was held at 3 Torr, the BDMABB vessel was heated to 50° C., the BDMABB was bubbled with 50 sccm of argon for 3 seconds to deliver the chemical, the chamber was then purged with argon for 20 seconds to remove excess BDMABB, an then either NH₃ or N₂ was flowed along with argon and a 200 W plasma was struck for 5 seconds followed by another 20 second purge to remove excess N₂ or NH₃. This process was then repeated for a select number of cycles. The results of analytical analysis are summarized in Table 3 below.

TABLE 3
Analytical summary for films deposited from
BDMABB using both N₂ and NH₃ PEALD process.

| | | XPS (at. %) | | XRR | |
|---|---|---|---|---|---|
| Plasma | Temperature | B/N/C/O/Br | XRD | (g/cc) | AFM |
| N₂ | 350° C. | 53.3/36.3/7.1/3.3/ | Amorphous | 1.96 | 2.05 |
| | | ND | | | (nm) |
| NH₃ | 350° C. | 56.0/38.5/2.8/2.7/ | Amorphous | 2.2 | 0.44 |
| | | ND | | | (Rq) |

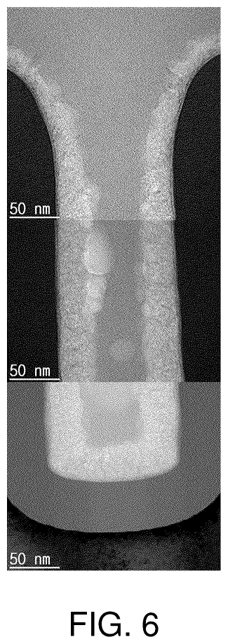

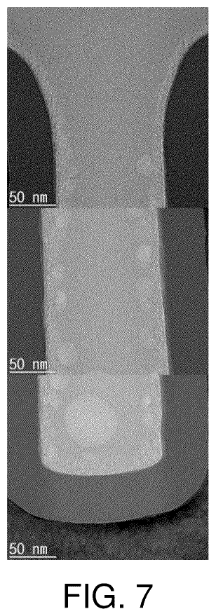

Surprising was that the TEM images of the films on high AR patterned films showed that the deposition shows some “bottom-up” fill characteristics. Although the films were relatively rough, the bottom up is important to deposit seam-free features. Note also that the aspect ratio of the features was only 5:1. FIG. 6 shows the TEM of a film deposited onto a high AR patterned feature using N₂ PEALD. Although the film is relatively rough the TEM shows significantly more film deposition at the bottom of the feature (˜37 nm) compared to at the top (˜23 nm), which represents ˜160% more film (SC) at the bottom than at the top. The film deposition at the shoulder feature is ˜26 nm (SC=˜113%), while film deposition at the middle is ˜34 nm (SC=˜148%). FIG. 7 shows the TEM of a film deposited onto a high AR ratio patterned feature using NH₃ PEALD. These films are smoother and do not show as much difference in film thickness between top and bottom, but there is still a slightly thicker film at the bottom of the feature, 17 nm (SC=˜106%) compared to the film at the top of the feature, 16 nm.

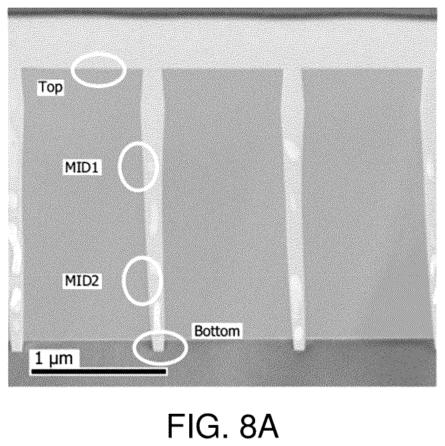

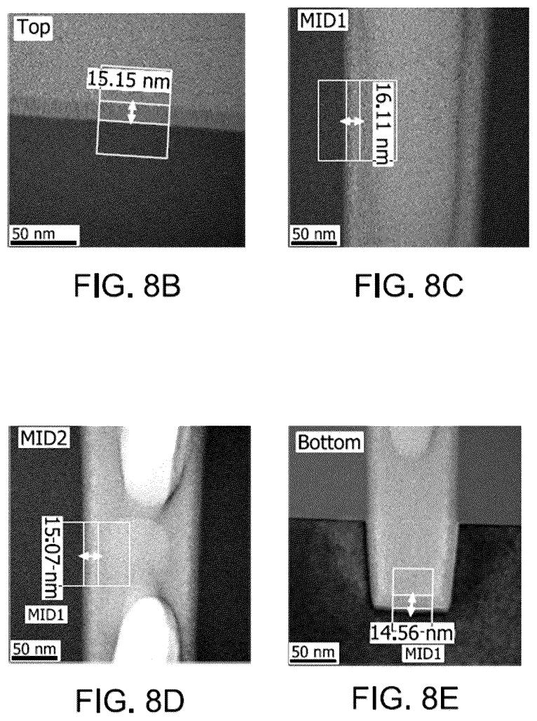

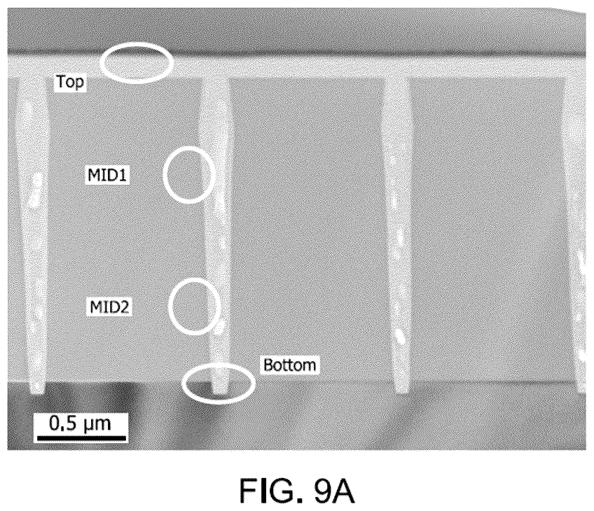

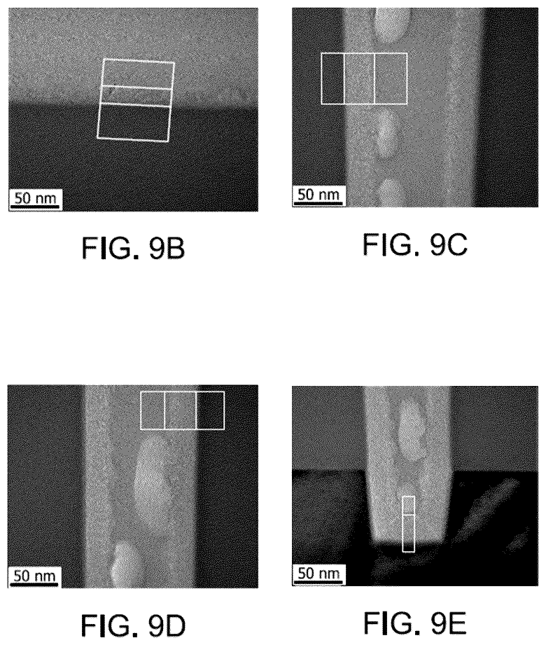

FIGS. 8 and 9 are TEM images for 17:1 high aspect ratio features. FIG. 8 reveals very good conformality for the NH₃ PEALD films. Further, FIG. 9 reveals a bottom thick deposition for the N₂ PEALD films, with significantly more film deposition at the bottom of the feature (˜33 nm) compared to at the top (˜23 nm), which represents ˜143% more film (SC) at the bottom than at the top. The film thickness measurement at the MID1 location is ˜32 nm (SC=˜139%), and the film thickness measurement at the MID1 location is ˜28 nm (SC=˜122%).

Surface features having a 5:1 aspect ratio were wet etched by dipping the surface in DHF for 20 minutes. The sidewalls etched slightly faster than the bottom: 0.25 A/minute on the side vs 0.04 Å/minute on the bottom for the NH₃ PEALD films; and 0.57 Å/minute for the side and 0.06 Å/minute on the bottom for the N₂ PEALD films.

The foregoing description is intended primarily for purposes of illustration. Although the invention has been shown and described with respect to an exemplary embodiment thereof, it should be understood by those skilled in the art that the foregoing and various other changes, omissions, and additions in the form and detail thereof may be made therein without departing from the spirit and scope of the invention.

1. A boron-containing precursor for use in depositing a boron-containing film having the structure of Formula I:
B(NR¹R²)ₙX₃₋ₙ (I),
wherein
R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group;
R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group;
X is Cl, Br, I, or F; and
n=1 or 2,
wherein R¹ and R² are optionally linked together to form a ring selected from a substituted or unsubstituted aromatic ring or a substituted or unsubstituted aliphatic ring, and wherein R¹ and R² may be the same moiety or different moieties.

2. The boron-containing precursor of claim 1 wherein R¹ and R² are linked together to form a cyclic ring.

3. The boron-containing precursor of claim 2 wherein R¹ and R² are selected from a linear or a branched C₃ to C₆ alkyl group and are linked to form the cyclic ring.

4. The boron-containing precursor of claim 1 wherein R¹ and R² are not linked together to form a ring.

5. The boron-containing precursor of claim 1 wherein R¹ and R² are different.

6. The boron-containing precursor of claim 1 wherein R¹ and R² are the same.

7. The boron-containing precursor of claim 1 comprising at least one precursor selected from the group consisting of bis(dimethylamino)chloroborane, bis(dimethylamino)bromoborane, bis(dimethylamino)iodoborane, bis(diethylamino)chloroborane, bis(diethylamino)bromoborane, bis(diethylamino)iodoborane, bis(ethylmethylamino)chloroborane, bis(ethylmethylamino)bromoborane, bis(ethylmethylamino)iodoborane; (di-iso-propylamino)dichloroborane, (di-iso-propylamino)dibromoborane, (di-iso-propylamino)diiodoborane (pyrrolidino)chloroborane, (pyrrolidino)bromoborane, (pyrrolidino)iodoborane, (2-methyl-pyrrolidino)chloroborane, (2-methyl-pyrrolidino)bromoborane, (2-methyl-pyrrolidino)iodoborane, (piperidino)chloroborane, (piperidino)bromoborane, (piperidino)iodoborane, (2,6-dimethyl-piperidino)dichloroborane, (2,6-dimethyl-piperidino)dibromoborane, and (2,6-dimethyl-piperidino)diiodoborane.

8. The boron-containing precursor of claim 7 wherein the boron-containing recursor comprises bis(dimethylamino)bromoborane.

9. The boron-containing precursor of claim 1 comprising at least one precursor selected from the group consisting of

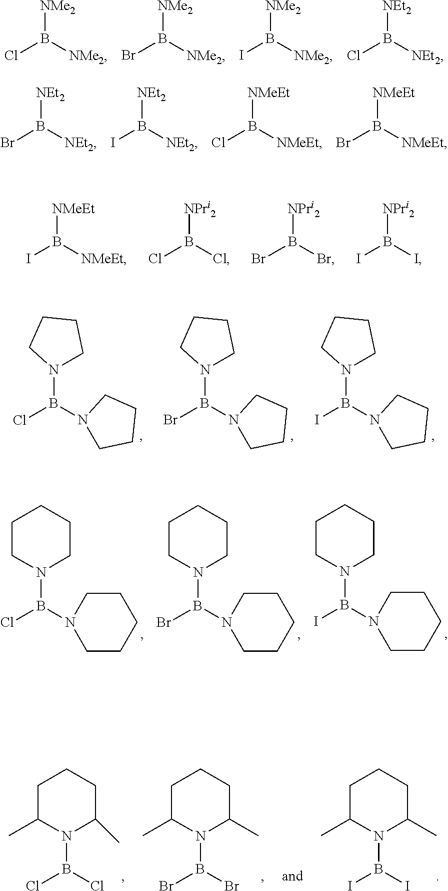

10. A composition comprising:
(a) at least one compound having the structure of Formula I:
B(NR¹R²)ₙX₃₋ₙ (I),
wherein
R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group;
R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group;
X is Cl, Br, I, or F; and
n=1 or 2,
wherein R¹ and R² are optionally linked together to form a ring selected from a substituted or unsubstituted aromatic ring or a substituted or unsubstituted aliphatic ring, and wherein R¹ and R² may be the same moiety or different moieties; and
(b) a solvent wherein the solvent has a boiling point and wherein the difference between the boiling point of the solvent and that of the at least one boron-containing precursor is 40° C. or less.

11. The composition of claim 10 wherein the solvent comprises at least one selected from the group consisting of ether, tertiary amine, alkyl hydrocarbon, aromatic hydrocarbon, and tertiary aminoether.

12. The composition of claim 10 wherein R¹ and R² are linked together to form a cyclic ring.

13. The composition of claim 12 wherein R¹ and R² are selected from a linear or a branched C₃ to C₆ alkyl group and are linked to form the cyclic ring.

14. The composition of claim 10 wherein R¹ and R² are not linked together to form a ring.

15. The composition of claim 10 wherein R¹ and R² are different.

16. The composition of claim 10 wherein R¹ and R² are the same.

17. The composition of claim 10 comprising at least one precursor selected from the group consisting of bis(dimethylamino)chloroborane, bis(dimethylamino)bromoborane, bis(dimethylamino)iodoborane, bis(diethylamino)chloroborane, bis(diethylamino)bromoborane, bis(diethylamino)iodoborane, bis(ethylmethylamino)chloroborane, bis(ethylmethylamino)bromoborane, bis(ethylmethylamino)iodoborane; (di-iso-propylamino)dichloroborane, (di-iso-propylamino)dibromoborane, (di-iso-propylamino)diiodoborane (pyrrolidino)chloroborane, (pyrrolidino)bromoborane, (pyrrolidino)iodoborane, (2-methyl-pyrrolidino)chloroborane, (2-methyl-pyrrolidino)bromoborane, (2-methyl-pyrrolidino)iodoborane, (piperidino)chloroborane, (piperidino)bromoborane, (piperidino)iodoborane, (2,6-dimethyl-piperidino)dichloroborane, (2,6-dimethyl-piperidino)dibromoborane, and (2,6-dimethyl-piperidino)diiodoborane.

18. The composition of claim 17 wherein the boron-containing recursor comprises bis(dimethylamino)bromoborane.

19. The composition of claim 10 comprising at least one precursor selected from the group consisting of

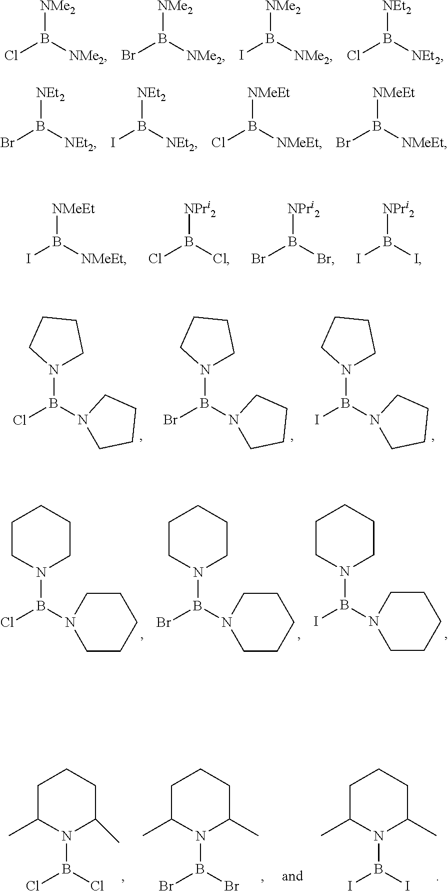

20. A method for depositing a boron-containing film onto at least a surface of a substrate having one or more features which comprises the steps of:
a. providing the substrate in a reactor;
b. forming the boron-containing film on the surface in a deposition process selected from a chemical vapor deposition and atomic layer deposition process using a boron-containing precursor selected from a compound having the structure of Formula I:
B(NR¹R²)ₙX₃₋ₙ (I),
wherein
R¹ is selected from a linear C₁ to C₁₀ alkyl group, a branched C₃ to C₁₀ alkyl group, a linear or branched C₃ to C₁₀ alkenyl group, a linear or branched C₃ to C₁₀ alkynyl group, a C₁ to C₆ dialkylamino group, an electron withdrawing group, and a C₄ to C₁₀ aryl group;
R² is selected from hydrogen, a linear C₁ to C₁₀ alkyl group, a branched C₃ to C₁₀ alkyl group, a linear or branched C₃ to C₆ alkenyl group, a linear or branched C₃ to C₆ alkynyl group, a C₁ to C₆ dialkylamino group, a C₆ to C₁₀ aryl group, a linear or branched C₁ to C₆ fluorinated alkyl group, an electron withdrawing group, and a C₄ to C₁₀ aryl group;
X is Cl, Br, I, or F; and
n=1 or 2,
wherein R¹ and R² are optionally linked together to form a ring selected from a substituted or unsubstituted aromatic ring or a substituted or unsubstituted aliphatic ring, and wherein R¹ and R² may be the same moiety or different moieties;
c. purging the reactor with a purge gas;
d. providing a nitrogen-containing source to deposit the film onto the at least one surface;
e. purging the reactor with a purge gas;
f. optionally introducing into the reactor at least one silicon-containing source;
g. purging the reactor with a purge gas after step f, if performed;
h. providing a nitrogen-containing source to deposit the film onto the at least one surface; and
i. purging the reactor with a purge gas,
wherein steps b through i are repeated until a desired thickness of the film is obtained.

21. The method of claim 20 wherein R¹ and R² are linked together to form a cyclic ring.

22. The method of claim 21 wherein R¹ and R² are selected from a linear or a branched C₃ to C₆ alkyl group and are linked to form the cyclic ring.

23. The method of claim 20 wherein R¹ and R² are not linked together to form a ring.

24. The method of claim 20 wherein R¹ and R² are different.

25. The method of claim 20 wherein R¹ and R² are the same.

26. The method of claim 20 wherein the at least one boron-containing precursor is selected from the group consisting of bis(dimethylamino)chloroborane, bis(dimethylamino)bromoborane, bis(dimethylamino)iodoborane, bis(diethylamino)chloroborane, bis(diethylamino)bromoborane, bis(diethylamino)iodoborane, bis(ethylmethylamino)chloroborane, bis(ethylmethylamino)bromoborane, bis(ethylmethylamino)iodoborane; (di-iso-propylamino)dichloroborane, (di-iso-propylamino)dibromoborane, (di-iso-propylamino)diiodoborane (pyrrolidino)chloroborane, (pyrrolidino)bromoborane, (pyrrolidino)iodoborane, (2-methyl-pyrrolidino)chloroborane, (2-methyl-pyrrolidino)bromoborane, (2-methyl-pyrrolidino)iodoborane, (piperidino)chloroborane, (piperidino)bromoborane, (piperidino)iodoborane, (2,6-dimethyl-piperidino)dichloroborane, (2,6-dimethyl-piperidino)dibromoborane, and (2,6-dimethyl-piperidino)diiodoborane.

27. The method of claim 26 wherein the boron-containing precursor comprises bis(dimethylamino)bromoborane.

28. The method of claim 20 wherein steps f and g are performed and the at least one silicon-containing source is selected from the group consisting of trisilylamine (TSA), bis(disiylamino)silane, bis(tert-butylamino)silane (BTBAS), bis(dimethylamino)silane, bis(diethylamino)silane, bis(ethylmethylamino)silane, tris(dimethylamino)silane, tris(ethylmethylamino)silane, tetrakis)dimethylamino)silane, di-iso-propylaminosilane, di-sec-butylaminosilane, di-tert-butylaminosilane, 2,6-dimethylpiperidinosilane, 2,2,6,6-tetramethylpiperidinosilane, cyclohexyl-iso-propylaminosilane, phenylmethylaminosilane, phenylethylaminodisilane, di-cyclohexylaminosilane, di-iso-propylaminodisilane, di-sec-butylaminodisilane, di-tert-butylaminodisilane, 2,6-dimethylpiperidinodisilane, 2,2,6,6-tetramethylpiperidinodisilane, cyclohexyl-iso-propylaminodisilane, phenylmethylaminodisilane, phenylethylaminodisilane, di-cyclohexylaminodisilane, dimethylaminotrimethylsilane, dimethylaminotrimethylsilane, di-iso-propylaminotrimethylsilane, piperidinotrimethylsilane, 2,6-dimethylpiperidinotrimethylsilane, di-sec-butylaminotrimethylsilane, iso-propyl-sec-butylaminotrimethylsilane, tert-butylaminotrimethylsilane, iso-propylaminotrimethylsilane, diethylaminodimethylsilane, dimethylaminodimethylsilane, di-iso-propylaminodimethylsilane, piperidinodimethylsilane, 2,6-dimethylpiperidinodimethylsilane, di-sec-butylaminodimethylsilane, iso-propyl-sec-butylaminodimethylsilane, tert-butylaminodimethylsilane, iso-propylaminodimethylsilane, tert-pentylaminodimethylaminosilane, bis(dimethylamino)methylsilane, bis(diethylamino)methylsilane, bis(di-iso-propylamino)methylsilane, bis(iso-propyl-sec-butylamino)methylsilane, bis(2,6-dimethylpiperidino)methylsilane, bis(iso-propylamino)methylsilane, bis(tert-butylamino)methylsilane, bis(sec-butylamino)methylsilane, bis(tert-pentylamino)methylsilane, di-iso-propylaminodisilane, and di-sec-butylaminodisilane, di-iso-propylaminotrisilylamine, diethylaminotrisilylamine, iso-propylaminotrisilylamine, and cyclohexylmethylaminotrisilylamine, 2-dimethylamino-2,4,4,6,6-pentamethylcyclotrisiloxane, 2-diethylamino-2,4,4,6,6-pentamethylcyclotrisiloxane, 2-ethylmethylamino-2,4,4,6,6-pentamethylcyclotrisiloxane, 2-iso-propylamino-2,4,4,6,6-pentamethylcyclotrisiloxane, 2-dimethylamino-2,4,4,6,6,8,8-heptamethylcyclotetrasiloxane, 2-diethylamino-2,4,4,6,6,8,8-heptamethylcyclotetrasiloxane, 2-ethylmethylamino-2,4,4,6,6,8,8-heptamethylcyclotetrasiloxane, 2-iso-propylamino-2,4,4,6,6,8,8-heptamethylcyclotetrasiloxane, 2-dimethylamino-2,4,6-trimethylcyclotrisiloxane, 2-diethylamino-2,4,6-trimethylcyclotrisiloxane, 2-ethylmethylamino-2,4,6-trimethylcyclotrisiloxane, 2-iso-propylamino-2,4,6-trimethylcyclotrisiloxane, 2-dimethylamino-2,4,6,8-tetramethylcyclotetrasiloxane, 2-diethylamino-2,4,6,8-tetramethylcyclotetrasiloxane, 2-ethylmethylamino-2,4,6,8-tetramethylcyclotetrasiloxane, and 2-iso-propylamino-2,4,6,8-tetramethylcyclotetrasiloxane, 2-pyrrolidino-2,4,6,8-tetramethylcyclotetrasiloxane, and 2-cyclohexylmethylamino-2,4,6,8-tetramethylcyclotetrasiloxane.

29. The boron-containing precursor of claim 1 selected from the group consisting of bis(ethylmethylamino)chloroborane, bis(ethylmethylamino)bromoborane, bis(ethylmethylamino)iodoborane; (2-methyl-pyrrolidino)chloroborane, (2-methyl-pyrrolidino)bromoborane, (2-methyl-pyrrolidino)iodoborane, (2,5-di-methyl-pyrrolidino)chloroborane, (2,5-dimethyl-pyrrolidino)bromoborane, and (2,5-dimethyl-pyrrolidino)iodoborane.

30. The composition of claim 10 wherein the at least one compound having the structure of Formula I is at least one selected from the group consisting of bis(ethylmethylamino)chloroborane, bis(ethylmethylamino)bromoborane, bis(ethylmethylamino)iodoborane; (2-methyl-pyrrolidino)chloroborane, (2-methyl-pyrrolidino)bromoborane, (2-methyl-pyrrolidino)iodoborane, (2,5-di-methyl-pyrrolidino)chloroborane, (2,5-dimethyl-pyrrolidino)bromoborane, and (2,5-dimethyl-pyrrolidino)iodoborane.

31. The method of claim 20 wherein the boron-containing precursor is at least one selected from the group consisting of bis(ethylmethylamino)chloroborane, bis(ethylmethylamino)bromoborane, bis(ethylmethylamino)iodoborane; (2-methyl-pyrrolidino)chloroborane, (2-methyl-pyrrolidino)bromoborane, (2-methyl-pyrrolidino)iodoborane, (2,5-di-methyl-pyrrolidino)chloroborane, (2,5-dimethyl-pyrrolidino)bromoborane, and (2,5-dimethyl-pyrrolidino)iodoborane.

32. The method of claim 20 wherein the substrate surface comprises at least one or more features having a bottom surface and at least one sidewall surface, and wherein the film is formed with a growth rate that is higher on the bottom surface than on the at least one sidewall surface.

33. The method of claim 20 wherein the nitrogen-containing source is selected from the group consisting of N₂ and NH₃.
